(19) United States
(12) Patent Application Publication
(10) Pub. No.: US 2018/0207901 A1
(43) Pub. Date: Jul. 26, 2018

(54) HEAT SPREADING STRUCTURE AND METHOD FOR FORMING THE SAME

(71) Applicant: 3M INNOVATIVE PROPERTIES COMPANY, St. Paul, MN (US)

(72) Inventors: Pei Tien, Taiwan (CN); Chao-Yuan Wang, Taiwan (CN); Ching-Yi Liu, Taiwan (CN)

(21) Appl. No.: 15/745,724

(22) PCT Filed: Jul. 20, 2015
(86) PCT No.: PCT/US2015/041054

§ 371 Date: Jan. 18, 2018

(51) Int. Cl. B32B 3/26; H05K 7/20; B32B 15/04; B32B 15/20; B32B 37/12; B32B 37/18; B32B 38/00; C09J 9/00; C09J 7/29; C09J 7/38

(52) U.S. Cl. CPC B32B 3/266; H05K 7/20509; B32B 15/043; B32B 15/20; B32B 37/1284; G06F 1/203; B32B 38/0004; C09J 9/00; C09J 7/29; C09J 7/385; B32B 37/18

(57) ABSTRACT

The present invention provides a heat spreading structure comprising a first conductive layer and a composite layer that sequentially comprises a structured adhesive layer and a second conductive layer having a coating on the first conductive layer, wherein the structured adhesive layer comprises at least one polymeric region and at least one void region. The composite layer further has a grounding opening exposing a part of the first conductive layer for grounding purposes. The present invention also provides a heat spreading tape and a method for forming the same.

### FIELD OF THE INVENTION

The present invention relates to a heat spreading structure of electronic apparatus, and particularly to a heat spreading tape which is designed to pursue for thinner and multifunctional characterizations.

### BACKGROUND OF THE INVENTION

Along with continuous advance of electronic sciences and technologies, various electronic products are more and more widely used. The electronic components of such products inevitably generate a substantial amount of heat. If not efficiently dissipated, heat will accumulate around the source to cause overheating of a local section of the surface of the electronic component. Conventionally, a heat spreader should be used to transfer and dissipate heat from the source to prevent it from concentrating and avoid abnormal raise of the localized temperature.

Graphite is a commonly used material for making a heat spreader, since it has very good thermal conductivity. However, it is expensive and very brittle. U.S. Pat. No. 3,404,061, entitled “Flexible graphite material of expanded particles compressed together,” describes a process for creating a binder-free flexible graphite film by expanding and then compressing acid-treated expandable graphite particles. U.S. Pat. No. 6,432,336 B1, entitled “Flexible graphite article and method of manufacture,” describes an improvement of the process in U.S. Pat. No. 3,404,061 for creating a flexible graphite film, such as a resin impregnated graphite film with enhanced isotopic (or omni-directional) properties for use as thermal management material. However, graphite cannot provide grounding function even with the foregoing modification.

A variety of thermally-conductive materials, e.g., a heat-conductive metal such as copper or a heat-conductive ceramic or composite material, have been developed to replace graphite for forming a heat spreading tape for application to a heat source of an electronic component. The heat spreading tape is normally a plate-shaped structure, and includes at least three layers. A common design of prior art heat spreading tapes is shown in FIG. 1. The heat spreading tape 10 of FIG. 1 typically includes a double adhesive tape 12, a conductive layer 14, an adhesive layer 16, a conductive layer 18, an adhesive layer 20, a conductive layer 22, and an insulation layer 24. The insulation layer 24 is typically an adhesive layer, such as a tape comprising a PET layer, a gray ink layer and an adhesive layer, and normally has a thickness of about 15 μm to about 25 μm. In addition, a portion of the insulation layer 24 can be peeled off, such that a portion of the conductive layer 22 will directly face outward for grounding purposes. When in use, the insulation layer 24 is provided at a heat source 26, the middle conductive layers 14, 18 and 22 are responsible for transferring heat from the heat source 26, and the double adhesive tape 12 is laminated on an outer surface of the electronic apparatus (not shown). When heat is dissipated from the heat source, it will accumulate in the insulation layers and then transferred to the conductive layers. Therefore, if the insulation layers are too thick, heat transfer to the conductive layers will be delayed, resulting in diminished performance of the electronic product.

Furthermore, it has been a long-standing trend to develop lighter, thinner and multifunctional products. The applicant thus attempts to provide a thinner heat spreader for electronic apparatus with the same or increased thermal transfer performance and multifunctional characteristics.

### SUMMARY OF THE INVENTION

A primary object of the present invention is to provide a heat spreading structure of electronic apparatus, which has multifunctional characterizations and is able to quickly and uniformly spread and outward dissipate the heat from a heat source so as to avoid concentration of the heat and abnormal rise of the temperature of a local section of the electronic apparatus.

According to the present invention, the heat spreading structure comprises a first conductive layer, and a composite layer formed on the first conductive layer; the composite layer sequentially comprising a structured adhesive layer and a second conductive layer having a coating thereon; wherein the composite layer has a grounding opening exposing a part of the first conductive layer, and the structured adhesive layer comprises at least one polymeric region and at least one void region.

It is a further object of the present invention to provide a heat spreading tape, which comprises the aforementioned heat spreading structure and an adhesive layer for easy use.

It is another object of the present invention to provide a method for forming the heat spreading structure and the heat spreading tape.

It is another object of the present invention to provide a heat conductive and electronic insulation layer for applying in the aforementioned heat spreading structure, wherein the heat conductive and electronic insulation layer comprises a conductive layer with a coating on the conductive layer.

### BRIEF DESCRIPTION OF THE DRAWINGS

The present invention will be more fully understood from the detailed description and accompanying drawings given below, which is for illustration only, and thus is not limitative of the present invention, and wherein:

FIG. 1 is a schematic view of a prior art heat spreading tape; and

FIG. 2 is a schematic view of a heat spreading structure according to a preferred embodiment of the present invention.

FIG. 3 is a schematic view of a heat spreading tape according to a preferred embodiment of the present invention.

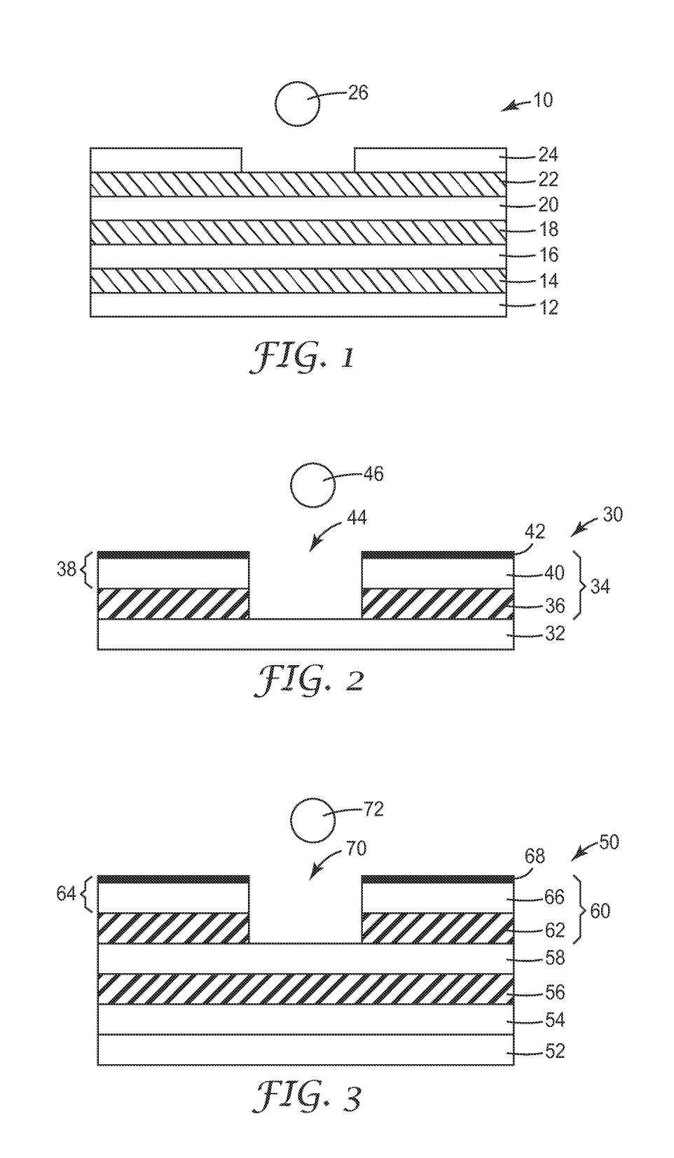

### DETAILED DESCRIPTION OF PREFERRED EMBODIMENTS OF THE INVENTION

Some embodiments of the present disclosure will be described hereinafter in detail with reference to the attached drawings, wherein the like reference numerals refer to the like elements. The present disclosure may, however, be embodied in many different forms and should not be construed as being limited to the embodiment set forth herein; rather, these embodiments are provided so that the present disclosure will be thorough and complete, and will fully convey the concept of the disclosure to those skilled in the art. FIG. 2 is a schematic view of a heat spreading structure according to a preferred embodiment of the present invention. As shown in FIG. 2, the heat spreading structure 30 comprises a first conductive layer 32, and a composite layer 34 formed on the first conductive layer 32. The composite layer 34 comprises a structured adhesive layer 36 and a heat conductive and electronic insulation layer 38 having a second conductive layer 40 with a coating 42 thereon. The composite layer 34 has a grounding opening 44 exposing a part of the first conductive layer 32, and is provided at a heat source 46.

According to one aspect of the present invention, the heat spreading structure may further comprise a plurality of conductive layers and/or a plurality of adhesive layers formed between the composite layer and the first conductive layer, wherein the conductive layers and the adhesive layers are alternately arranged with each other. The total thickness of the heat spreading structure is not specifically limited and may be of any value that is suitable for the present invention; preferably it is thinner than conventional structures. In preferred embodiments of the present invention, a total thickness of the heat spreading structure ranges from about 30 μm to about 140 μm, preferably about 50 μm to about 100 μm, more preferably about 90 μm.

In a preferred embodiments of the present invention, the first conductive layer, the second conductive layer and the additional conductive layers are not particularly limited, examples thereof including, but not limited to, copper, aluminum, gold, silver, zinc, iron, nickel, platinum, alloys thereof, or combinations thereof, preferably cooper or aluminum. The thickness of each conductive layer is not specifically limited and may be of any value that is suitable for the present invention. Typically, the conductive layers each independently has a thickness of about 5 μm to about 50 μm, preferably about 15 μm to about 35 μm or about 25 μm to about 30 μm.

According to one aspect of the present invention, the coating of the heat conductive and electronic insulation layer provides the insulation function for the heat spreading structure. The coating comprises a layer of ink and titanium dioxide (TiO₂), wherein the ink can be gray ink, but not limited thereto. In a preferred embodiment of the present invention, the coating may merely consists of a layer of ink mixing with TiO₂. The method of forming the coating on the conductive layer is not particularly limited, and conventionally known methods may be applicable. An example of the method of forming the coating includes a gravure coating or screen printing technique. The thickness of the coating is not specifically limited and may be of any value that is suitable for the present invention. In preferred embodiments of the present invention, the coating of the heat conductive and electronic insulation layer of the composite layer has a thickness of about 1 μm to about less than 15 μm, preferably about 2 μm to about 10 μm, about 2 μm to about 8 μm, about 4 μm to about 6 μm, more preferably about 2 μm to about 5 μm.

According to one aspect of the present invention, the structured adhesive layers and the additional adhesive layers are not particularly limited, examples thereof including, but not limited to, thermoset adhesive, pressure sensitive adhesive, thermoplastic elastomer adhesive, hot metal adhesive or combinations thereof. The thickness of each adhesive layer is not specifically limited and may be of any value that is suitable for the present invention. Typically, the adhesive layers each independently has a thickness of about 2 μm to about 50 μm, preferably about 5 μm to about 20 μm, more preferably about 5 μm to about 10 μm.

In a preferred embodiment of the present invention, each adhesive layer can be independently a structured adhesive layer that comprises at least one polymeric region and at least one void region. Preferably, a plurality of polymeric regions and a plurality of void regions are provided. In some embodiments, the polymeric region(s) of the structured adhesive layer comprises adhesive, examples thereof including, but not limited to thermoset adhesive, pressure sensitive adhesive, thermoplastic elastomer adhesive, hot metal adhesive or combinations thereof. In a preferred embodiment of the present invention, the polymeric region(s) of the structured adhesive layer may comprise adhesive selected from acrylic pressure sensitive adhesive, rubber pressure sensitive adhesive, acrylic adhesive, polyurethane adhesive, polyimide adhesive, silicone adhesive, epoxy adhesive and combinations thereof.

In the structured adhesive layers, the structure of the void region(s) is not limited and may include gaps, channels, pores, holes, grooves, and the like. The void region(s) may also include one or more gases, e.g. air, nitrogen, carbon dioxide, and combinations thereof. The structure of the void region(s) may include combinations of different structures, e.g. grooves and pores. The thickness and a total volume of the void region(s) formed in the structured adhesive layers are not specifically limited and may be of any values that are suitable for the present invention. Typically, the void region(s) may have a height of about 2 μm to about 50 μm, preferably about 5 μm to about 20 μm, more preferably about 5 μm to about 10 μm. A total volume of the void region(s) formed in the structured adhesive layer ranges from about 20% to about 90% of the volume of the structured adhesive layer; preferably, a total volume of the void region(s) formed in the structured adhesive layer is about one third of the volume of the structured adhesive layer. According to one aspect of the present invention, the composite layer of the heat spreading structure further has a grounding opening exposing a part of the conductive layer for grounding purposes. The method of forming the grounding opening in the composite layer is not particularly limited, and conventionally known methods may be applicable. An example of the method of forming the grounding opening includes a kiss-cut technology.

In a preferred embodiment of the present invention, the plurality of the first conductive layer, the second conductive layer, and the additional conductive layers are preferably electrically connected to each other for grounding purposes. The method of electrically connecting the conductive layers is not particularly limited, and conventionally known methods may be applicable. Examples of electrically connecting the conductive layers include pressing or embossing portion(s) of the surface of the composite layer, or cutting an edge side of the layers by using a dull knife, such that the conductive layers are partially connected to each other.

According to the present invention, the heat spreading structure can be prepared by any methods known in the art. For example, it may be prepared by a) providing a first conductive layer, b) forming a composite layer sequentially comprising a structured adhesive layer and a heat conductive and electronic insulation layer having a second conductive layer with a coating thereon, and c) forming a grounding opening in the composite layer to expose a part of the first conductive layer.

The present invention also provides a heat spreading tape comprising the aforementioned heat spreading structure and a bottom adhesive layer attached to the first conductive layer opposite to the composite layer. The bottom adhesive layer is not particularly limited, examples thereof including, but not limited to, thermoset adhesive, pressure sensitive adhesive, thermoplastic elastomer adhesive, hot metal adhesive or combinations thereof. The thickness of the bottom adhesive layer is not specifically limited and may be of any value that is suitable for the present invention. Typically, the bottom adhesive layer has a thickness of about 2 μm to about 30 μm, preferably about 5 μm to about 15 μm, more preferably about 8 μm to about 10 μm. For grounding purposes, the bottom adhesive layer can be selected from electrically conductive adhesives. In a preferred embodiment of the present invention, the bottom adhesive layer is an electrically conductive double adhesive tape for easy use.

FIG. 3 is a schematic view of a heat spreading tape according to a preferred embodiment of the present invention. Referring to FIG. 3, the heat spreading tape 50 sequentially comprises a bottom adhesive layer 52, a first conductive layer 54, an adhesive layer 56, another conductive layer 58, and a composite layer 60 comprising an adhesive layer 62 and a heat conductive and electronic insulation layer 64 which comprise a (second) conductive layer 66 with a coating 68. The composite layer 60 has a grounding opening 70 exposing a part of the conductive layer 58, and is provided at a hear source 72. The following examples will exemplify aspects of the present invention and explain the technical features of the present invention, but are not intended to confine the scope of the present invention. Both modification and equivalent arrangement made readily by anyone skilled in the art fall within the scope claimed by the present invention, which shall be defined by the appended claims.

### EXAMPLES

Preparation of Comparative Heat Spreading Tape

18 μm Al layer purchased from CSALU company is provided and laminated on a double face tape 6604 A having a thickness of 40 μm purchased from 3M Company, then a structured adhesive layer with a thickness of 8 μm is formed on the Al layer opposite to the double face tape. The adhesive region and the void regions (air) of the structured adhesive layer are distributed alternatively in an angle of 45°, wherein the width of the adhesive region is 1 mm and the width of the air is 2 mm. The adhesive regions of the structured adhesive layer is selected from acrylic pressure sensitive adhesive with 94 parts by weight of 2-ethylhexyl acrylate (2-EHA) and 6 parts by weight of acrylic acid (AA) used as the monomer and coated by gravure coating. Another Al layer having a thickness of 35 μm, another structured adhesive layer having a thickness of 8 μm and another Al layer having a thickness of 35 μm are sequentially formed on the material, and a single face type 6T16G having a total thickness of 20 μm (comprising 12 μm PET layer, 3 μm gray ink layer, and 5 μm adhesive layer) purchased from 3M Company is laminated on the material. The resulting heat spreading tape has a total thickness of 164 μm (see Table 1).

TABLE 1

| Material | Thickness (μm) |
|---|---|
| Insulation layer (a single face tape 6T16G) | 20 |
| Al | 35 |
| Structured adhesive layer | 8 |
| Al | 35 |
| Structured adhesive layer | 8 |
| Al | 18 |
| Adhesive (a double face tape 6604) | 40 |
| Total thickness | 164 |

Preparation of a heat spreading tape of the present invention 18 μm Al layer purchased from CSALU company is provided and laminated on a double face tape UTC-10 having a thickness of 10 μm purchased from 3M Company, then a structured adhesive layer with a thickness of 8 μm is formed on the Al layer opposite to the double face tape. The adhesive regions and the void regions (air) of the structured adhesive layer are distributed alternatively in an angle of 45°, wherein the width of the adhesive region is 1 mm and the width of the air is 2 mm. The adhesive of the structured adhesive layer is selected from acrylic pressure sensitive adhesive with 94 parts by weight of 2-ethylhexyl acrylate (2-EHA) and 6 parts by weight of acrylic acid (AA) used as the monomer and coated by gravure coating, thereafter, another Al layer having a thickness of 18 μm, another structured adhesive layer having a thickness of 8 μm and another Al layer having a thickness of 35 μm are sequentially formed on the material, and finally a gray ink layer having a total thickness of 3 μm purchased from Hansin Mei Kuang ink company, Taiwan is coating on the material. The resulting heat spreading tape of the present invention has a total thickness of 100 μm (see Table 2).

TABLE 2

| Material | Thickness (μm) |
|---|---|
| Coating (a gray ink layer) | 3 |
| Al | 35 |
| Structured adhesive layer | 8 |
| Al | 18 |
| Structured adhesive layer | 8 |
| Al | 18 |
| Adhesive (a double coating tape UTC-10) | 10 |
| Total thickness | 100 |

### Results

A test method is used to evaluate the electrical properties of the two heat spreading tapes, wherein the comparative heat spreading tape (164 μm) and the heat spreading tape of the present invention (100 μm) are separately adhered to a 1 mm thickness PC/ABS board, and a thermal coupler is adhered to the side of PC/ABS board opposite to the heat spreading tapes. The heater, which is a hot meter bar (2.54 cm×2.54 cm) purchased from Long Win Company (Taiwan), and the heat spreading tapes have a distance of 1 mm therebetween. By heating the heater to 73° C. (similar to 1.5 W of CPU of 10.1′ tablet), the heat spreading results can be derived. Table 3 lists the results of the two heat spreading tapes. As shown in Table 3, the skin temperature with regard to the 100 μm tape of the present invention revealed 39° C., which is the same as that of the 164 μm one. That is, the heat spreading tape of the present invention, which is much thinner than the conventional heat spreading type, still has same performance as the thick one.

TABLE 3
10.1′ tablet

| Heat spreading tape | 164 μm | 100 μm |
|---|---|---|
| CPU loading 1.5 W (skin) | 39° C. | 39° C. |
| CPU loading 1.5 W (CPU) | 73° C. | 73° C. |

### The Electronic Insulation Capability Test of the Coating on the Conductive Layer of the Composite Layer

Insulation test is conducted via ASTM D1000.

The Comparative Example 1 of the coating/insulation layer is a commercialized available adhesive tape 6T16G form 3M Company.

The formulations of the Examples 1 and 2 and Comparative Example 2 of the coating are shown below, wherein ink comprising carbon black, TiO₂, solvents, and PU resin are purchased from Hansin Mei Kuang ink company.

It is to be understood that with the increasing of the thickness of the coating layer, the electronic insulation capability will be increased. As shown in Table 4 below, the electronic insulation coating of Comparative Example 1 is 20 μm and the breakdown voltage thereof is 3 KV, whereas the thickness of Example 1 and 2 is largely decreased to 3 μm but the electronic insulation capacity are 2 KV and 1 KV, respectively. In comparison with the standard of NEMA MW1000, the electronic insulation requirement of the thinnest insulating coating increasing for one side (0.0025 mm, single build minimum increasing diameter is 0.05 mm) of the minimum bare wire 0.048 mm (AWG size 44) is 300 V. Accordingly, it is to be understood that though the electronic insulation performance of Examples 1 and 2 are not as good as that of Comparative Example 1, with the reduction of coating thickness, the electronic insulation capacity of Examples 1 and 2 can not only satisfy the basic requirement per NEMA requirement still but also have a great improvement in comparison with a similar thickness coating in the standard of NEMA.

TABLE 4

| | | | | | | Break- |
|---|---|---|---|---|---|---|
| | Carbon | | Solvent | Solvent | | down |
| | black | TiO₂ | (Tolu- | (2-Buta- | PU | Voltage |
| | % | % | ene) | none) | resin | (KV) |
| Example 1 | 3 | 8 | 15 | 40 | 15 | 2 |
| Example 2 | 7 | 4 | 15 | 40 | 15 | 1 |
| Comparative | — | — | — | — | — | 3 |
| Example 1 | | | | | | |
| Comparative | 10 | 0 | 15 | 40 | 15 | 0.3 |
| Example 2 | | | | | | |

Given the above, the heat spreading structure and the heat spreading tape of the present invention are thinner than the conventional ones, have simple structures and are able to quickly and uniformly dissipate the heat generated by a heat source of the electronic apparatus so as to avoid concentration of the heat and abnormal rise of the temperature of a local section of the electronic apparatus. Moreover, the heating spreading structure of the present invention preferably has a grounding design and involves a metal conductive layer, so that it has multifunctional performance including good electromagnetic effects and grounding effects, as well as electronic insulation effects.

Although several embodiments have been shown and described, it would be appreciated by those skilled in the art that feature(s) in one embodiment will be interchangeable with those in another embodiment and, various changes or modifications may be made in these embodiments without departing from the principles and spirit of the disclosure, the scope of which is defined in the claims and their equivalents.

1. A heat spreading structure, comprising:
a first conductive layer; and
a composite layer formed on the first conductive layer, the composite layer sequentially comprising a structured adhesive layer and a second conductive layer having a coating thereon;
wherein the composite layer has a grounding opening exposing a part of the first conductive layer, and the structured adhesive layer comprises at least one polymeric region and at least one void region; and
wherein the coating comprises ink and titanium dioxide.

2. The heat spreading structure according to claim 1, wherein the first conductive layer and the second conductive layer are each independently selected from the group consisting of copper, aluminum, gold, silver, zinc, iron, nickel, platinum, alloys thereof, and combinations thereof.

3. (canceled)

4. The heat spreading structure according to claim 1, wherein the coating has a thickness of about 1 μm to about less than 15 μm.

5. The heat spreading structure according to claim 4, wherein the coating has a thickness of about 2 μm to about 5 μm.

6. The heat spreading structure according to claim 1, wherein the at least one polymeric region of the structured adhesive layer each independently comprises adhesive selected from the group consisting of thermoset adhesive, pressure sensitive adhesive, thermoplastic elastomer adhesive, hot metal adhesive and combinations thereof.

7. The heat spreading structure according to claim 6, wherein the at least one polymeric region of the structured adhesive layer each independently comprises adhesive selected from the group consisting of acrylic pressure sensitive adhesive, rubber pressure sensitive adhesive, acrylic adhesive, polyurethane adhesive, polyimide adhesive, silicone adhesive, epoxy adhesive and combinations thereof.

8. The heat spreading structure according to claim 1, wherein the at least one void region is selected from the group consisting of a gap, a channel, a pore, a hole, a groove, and combinations thereof.

9. The heat spreading structure according to claim 1, wherein the at least one void region contains one or more gases selected from the group consisting of air, nitrogen, carbon dioxide, and combinations thereof.

10. The heat spreading structure according to claim 1, wherein the at least one void region has a height of about 2 μm to about 50 μm.

11. The heat spreading structure according to claim 1, wherein a total volume of the void regions formed in the structured adhesive layer is from about 20% to about 90% of the volume of the structured adhesive layer.

12. The heat spreading structure according to claim 1, wherein a total volume of the void regions formed in the adhesive layer is about one third of the volume of the adhesive layer.

13. The heat spreading structure according to claim 1, wherein a total thickness of the heat spreading structure is from about 30 μm to about 140 μm.

14. The heat spreading structure according to claim 13, wherein a total thickness of the heat spreading structure is from about 50 μm to about 90 μm.

15. The heat spreading structure according to claim 1, further comprising a plurality of conductive layers and/or a plurality of adhesive layers formed between the composite layer and the first conductive layer, wherein the conductive layers and the adhesive layers are alternately arranged with each other.

16. The heat spreading structure according to claim 15, wherein the plurality of adhesive layers each independently comprises a structured adhesive layer.

17. The heat spreading structure according to claim 15, wherein the plurality of conductive layers are electrically connected to each other.

18. The heat spreading structure according to claim 1, wherein the heat spreading structure further comprises an adhesive layer attached to the first conductive layer opposite to the composite layer.

19. A heat spreading tape, comprising:
an adhesive layer;
a first conductive layer; and
a composite layer formed on the first conductive layer, the composite layer sequentially comprising a structured adhesive layer and a second conductive layer having a coating thereon;
wherein the composite layer has a grounding opening exposing a part of the first conductive layer, and the structured adhesive layer comprises at least one polymeric region and at least one void region.

20. A method for forming a heat spreading structure, comprising:
a) providing a first conductive layer;
b) forming a composite layer sequentially comprising a structured adhesive layer and a second conductive layer having a coating thereon on the first conductive layer, wherein the structured adhesive layer comprises at least one polymeric region and at least one void region; and
c) forming a grounding opening in the composite layer to expose a part of the first conductive layer.

21. (canceled)
